(19) United States
(12) Patent Application Publication
(10) Pub. No.: US 2003/0210064 A1
(43) Pub. Date: Nov. 13, 2003

(54) Testing apparatus for BGA IC

(76) Inventors: Yao-kui Huang, Hsin Tien City (TW); Cheng Fan Wang, Hsin Tien City (TW)

Correspondence Address: BIRCH STEWART KOLASCH & BIRCH, PO BOX 747, FALLS CHURCH, VA, 22040-0747, US

(21) Appl. No.: 10/410,216

(22) Filed: Apr. 10, 2003

(30) Foreign Application Priority Data
May 7, 2002 (TW) 091206425

(51) Int. Cl. G01R 31/02

(52) U.S. Cl. 324/755

(57) ABSTRACT

A testing apparatus for BGA IC comprises a test circuit board, a socket; and a plurality of detachable fixing units to detachably assemble the socket on the test circuit board. The socket comprises a socket body, a lid pivotally arranged on one end of the socket body to fix an IC on the socket body, and a plurality of conductive pins arranged in socket body to provide electric connection between the test circuit board and the IC. The lid has an upper locking unit locked to a lower locking unit of the socket body such that the IC can be firmly fixed on the socket body and leads contact balls of the IC are tightly connected to the corresponding conductive pins.

### FIELD OF THE INVENTION

The present invention relates to a testing apparatus for BGA IC, especially to a testing apparatus for BGA IC, which has a detachable testing socket.

### BACKGROUND OF THE INVENTION

The BGA (ball grid array) ICs are generally subjected to a component level test after encapsulation for finding and removing defected products. Moreover, to ensure the BGA ICs having normal operation on system level, a system level test is required. In the system level test, a packaged BGA IC under test is mounted on a test computer system to simulate certain function in real computer system. The test computer system has similar components as the ordinary computer system except a dedicated connector for the BGA IC to be tested. Therefore, the BGA IC to be tested can be simulated in a genuine condition.

With reference now to FIG. 4, a prior art testing apparatus for BGA ICs comprises a socket 100 and a testing board 200. The socket 100 comprises an accommodating recess 101 and a plurality of metal pins 102. The accommodating recess 101 is used to receive an IC. to be tested (not shown). The metal pins 102 are directly soldered to the testing board 200, thus providing electrical connection between the IC and the testing board 200 and fixing the socket 100 to the testing board 200.

In the above-mentioned testing apparatus for BGA IC, the socket 100 is directly soldered to the testing board 200. Therefore, once a metal pin 102 has contact problem with the testing board 200, the entire apparatus is broken down. Moreover, the IC is generally mounted into the accommodating recess 101 manually, which is inconvenient and finger syndrome is liable for operator.

### SUMMARY OF THE INVENTION

It is an object of the present invention to provide a testing apparatus for BGA IC with a testing circuit board and a removable socket. The socket can be detachably assembled to the testing circuit board to provide the flexibility for replacing testing circuit board and socket.

It is another object of the present invention to provide a testing socket for BGA IC to solve the problem of finger syndrome for operator.

To achieve the above objects, the present invention provides a testing apparatus for BGA IC comprising a test circuit board, a socket; and at least one detachable fixing unit to detachably assemble the socket on-the test circuit board. The socket comprises a socket body, a lid pivotally arranged on one end of the socket body to fix an IC on the socket body, and a plurality of conductive pins arranged in socket body to provide electric connection between the test circuit board and the IC. The lid has an upper locking unit locked to a lower locking unit of the socket body such that the IC can be firmly fixed on the socket body and leads of the IC are tightly connected to corresponding conductive pins. Therefore, the IC can be easily inserted into the socket without the hard pushing of the operator, which solves the problem of finger fatigue or syndrome of the operator.

The various objects and advantages of the present invention will be more readily understood from the following detailed description when read in conjunction with the appended drawing, in which:

### BRIEF DESCRIPTION OF DRAWING

FIG. 1 shows the perspective view of the present invention;

FIG. 2 shows the exploded view of the present invention;

FIG. 3 is a schematic view demonstrating the testing apparatus; and

FIG. 4 shows the perspective view of the prior art testing apparatus.

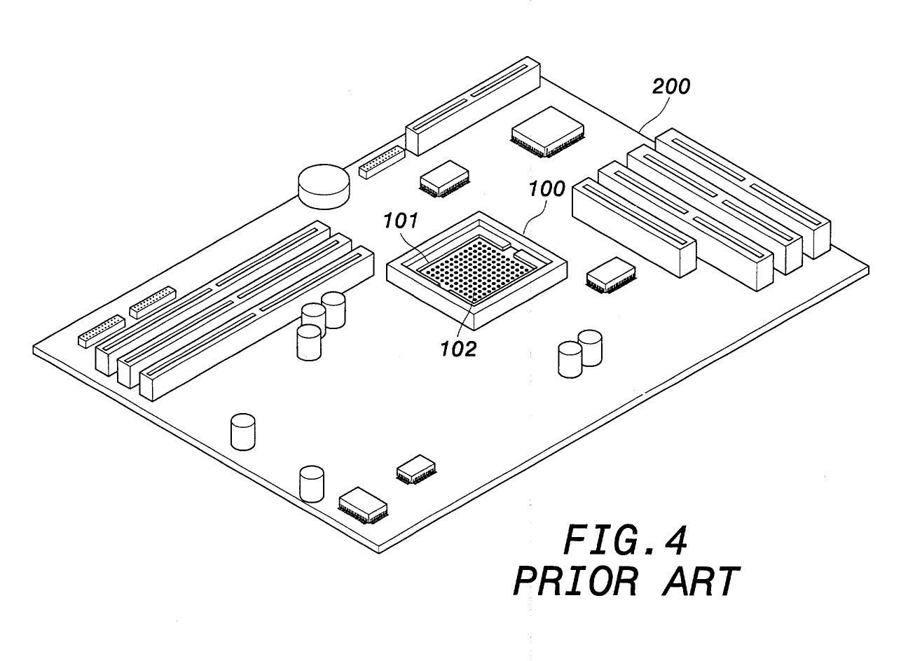

### DETAILED DESCRIPTION OF THE INVENTION

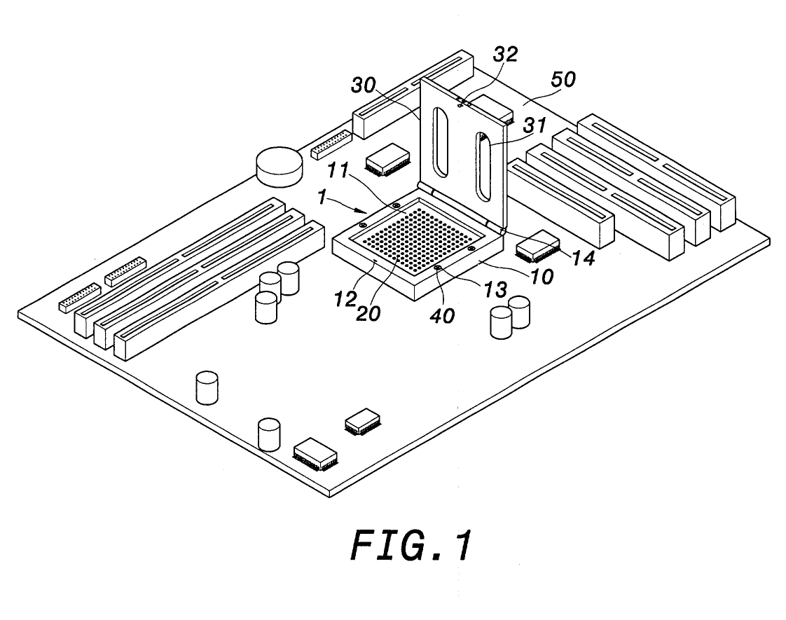

With reference to FIGS. 1 to 3, the present invention discloses a testing apparatus for BGA IC, which comprises a socket 1, and a testing board 50. The socket 1 comprises a plurality of removable fixing units 40. The fixing unit 40 can be assembled to or detached from the testing board 50 without damage. Of course, the assembly and detachment of the fixing unit 40 will not damage the socket 1 or the testing board 50. The testing board 50 is a circuit board 50 adapted for testing purpose. The testing board 50 can be a printed circuit board.

The socket 1 comprises a socket body 10, a plurality of conductive pins 20 and a lid 30, wherein the lid 30 is pivotally connected to one end of the socket. body 10 in order to fix an IC 60 on the socket body 10.

The conductive pins 20 are arranged on the socket body 10 to provide electrical connection between the testing board 50 and the IC 60.

With reference now to FIG. 1, this figure shows a perspective view of a preferred embodiment of the present invention. The socket body 10 has an accommodating recess 11 for the IC, a lower locking unit 12, a plurality of through holes 13 and a hinge 14. The upper cover 30 has a pair of openings 31 and an upper locking unit 32. The upper cover 30 is hinged to one side of the socket body 10 by the hinge 14. In practice, there can be only one opening 31 or a plurality of openings 31 on the upper cover 30. The conductive pins 20 are arranged in the accommodating recess 11. The fixing units 40 pass through the through holes 13 to fix the socket body 10 on the testing board 50.

The upper locking unit 32 is lockable to the lower locking unit 12 such that the end of the upper cover 30 with the upper locking unit 32 can be fixed on the socket body 10 and the contact balls (not shown) of the IC 60 are tightly connected to corresponding conductive pins 20.

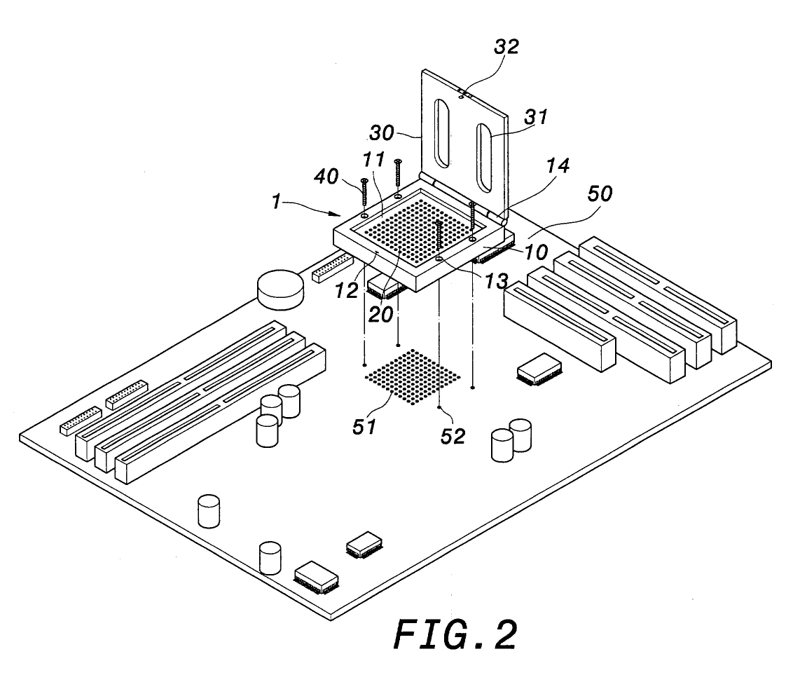

FIG. 2 shows the exploded view of the present invention, the testing board 50 has a plurality of conductive contacts 51 and a plurality of retaining holes 52. The fixing units 40 fix the socket body 10 on the testing board 50 with the help of the retaining holes 52. In the preferred embodiment of the present invention, the fixing unit 40 is bolt and nut or a screw and the retaining hole 52 is a threaded hole matching with the fixing unit 40.

The plurality of conductive contacts 51 are corresponding to the conductive pins 20 such that the testing board 50 are electrically connected to the IC and provide power to the IC.

Moreover, to enhance the hardness of the conductive contacts 51 and reduce the resistance change rate thereof, a gold layer (not shown) is provided over the conductive contacts 51. In the preferred embodiment of the present invention, the metal layer can be achieved by plating a gold layer with a thickness of 5-50μ inches. Therefore, the stability of the testing apparatus in high temperature and high frequency conditions can be enhanced. The lifetime of the testing board 50 is also increased. In another preferred embodiment of the present invention, noble metals such as silver and platinum can be used instead of gold to reach similar effect.

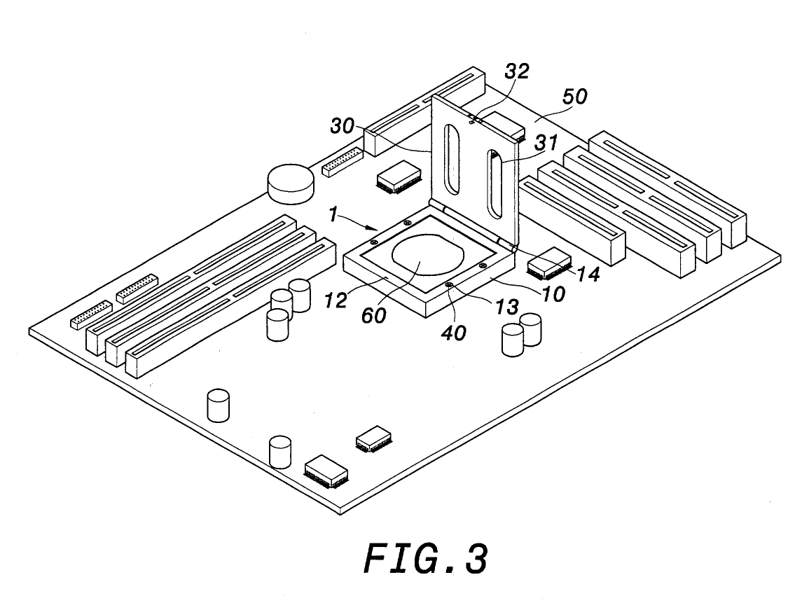

FIG. 3 is a schematic view demonstrating the testing apparatus. To test an IC 60, the IC 60 is firstly mounted on the accommodating recess 11 while the leads of the IC 60 are connected to corresponding pins 20. Afterward, the upper locking unit 32 is locked to the lower locking unit 12 such that the IC 60 is retained on the socket body 10 and the contact balls of the IC are in close contact with corresponding pins 20. Therefore, the IC can communicate with the testing board 50 through the pins 20 and the contacts 51 to transmit signals or to get electric power.

In the preferred embodiment of the present invention, the pins 20 can be POGO pins. The pogo pin includes a pin body and a pin head that can be withdrawn back into the pin body due to external forces exerting thereon. Therefore, the testing apparatus with such pogo pins has larger tolerance for solder ball height errors, which enhance contact between the pins and the solder balls and thus improving test accuracy .

In the preferred embodiment shown in FIGS. 1 to 3, the testing board 50 is exemplified with a motherboard. However, the present invention can also be applied to an add-on card.

To sum up, the testing apparatus for BGA IC has following advantages:

1. Easy to assemble onto and detach from a circuit board such that either the socket or the testing board 50 can be easily replaced separately.

2. The IC to be tested can be easily replaced to prevent finger fatigue or even finger syndrome of the operator.

3. The use of gold layer coated on the contact can enhance lifetime and stability of the testing apparatus.

4. The testing board can be reused after the socket is detached in the original way.

Although the present invention has been described with reference to the preferred embodiment thereof, it will be understood that the invention is not limited to the details thereof. Various substitutions and modifications have suggested in the foregoing-description, and other will occur to those of ordinary skill in the art. Therefore, all such substitutions and modifications are intended to be embraced within the scope of the invention as defined in the appended claims.

1. A testing apparatus for BGA IC, comprising
a test circuit board;
a socket; and
at least one detachable fixing unit to detachably assemble the socket on the test circuit board.

2. The testing apparatus for BGA IC as in claim 1, wherein the socket further comprising
a socket body;
a lid pivotally arranged on one end of the socket body for fixing an IC (integrated circuit) on the socket body; and
a plurality of conductive pins arranged in socket body for providing electric connection between the test circuit board and the IC.

3. The testing apparatus for BGA IC as in claim 2, wherein the socket body includes at least one through hole for the fixing unit.

4. The testing apparatus for BGA IC as in claim 2, wherein the test circuit board has at least one retaining hole corresponding to the fixing unit.

5. The testing apparatus for BGA IC as in claim 2, wherein the test circuit board has conductive contacts corresponding to the pins.

6. The testing apparatus for BGA IC as in claim 5, wherein a gold layer is formed on each of the conductive contacts.

7. The testing apparatus for BGA IC as in claim 6, wherein the gold layer has a thickness of 5-50μ inches.

8. The testing apparatus for BGA IC as in claim 1, wherein the fixing unit is bolt and nut.

9. The testing apparatus for BGA IC as in claim 2, wherein the socket body has an accommodating recess.

10. The testing apparatus for BGA IC as in claim 2, wherein a locking set is provided for the lid and the socket body to lock the lid and the socket body together.

11. The testing apparatus for BGA IC as in claim 2, wherein the pins are POGO pins.

12. The testing apparatus for BGA IC as in claim 2, wherein the lid has an opening.

13. The testing apparatus for BGA IC as in claim 2, wherein the lid has a plurality of openings.

14. A testing socket for BGA IC, comprising
a socket body
a lid pivotally arranged on one end of the socket body to fix an IC (integrated circuit) on the socket body; and
at least one detachable fixing unit to detachably assembled the socket on a test circuit board, and
a plurality conductive pins arranged in the socket body to provide electric connection between the test circuit board and the IC.

15. The testing socket for BGA IC as in claim 14, wherein the lid has at least one opening.

16. The testing socket for BGA IC as in claim 14, wherein the test circuit board has at least one retaining hole corresponding to the fixing unit.

17. The testing socket for BGA IC as in claim 14, wherein the test circuit board has conductive contacts corresponding to the pins.

18. The testing socket for BGA IC as in claim 14, wherein a noble metal layer is formed on each of the conductive contacts.

19. The testing socket for BGA IC as in claim 18, wherein the noble metal layer is a gold layer having a thickness of 5-50μ inches.

20. The testing apparatus for BGA IC as in claim 14, wherein the fixing unit is a screw.
